(19) United States
(12) Patent Application Publication
(10) Pub. No.: US 2020/0146176 A1
(43) Pub. Date: May 7, 2020

(54) THERMALLY CONDUCTIVE MATERIAL COMPRISING IONIC LIQUID AND ELECTRICAL DEVICES MADE THEREWITH

(71) Applicant: DUPONT ELECTRONICS, INC., Wilmington, DE (US)

(72) Inventors: JEFFREY SCOTT METH, LANDENBERG, PA (US); STEPHANIE A BERNARD, WILMINGTON, DE (US)

(21) Appl. No.: 16/673,029

(22) Filed: Nov. 4, 2019

Related U.S. Application Data
(60) Provisional application No. 62/755,808, filed on Nov. 5, 2018.

(51) Int. Cl. H05K 7/20; C08K 5/56; C09K 5/14

(52) U.S. Cl. CPC H05K 7/2039; C09K 5/14; C08K 5/56

(57) ABSTRACT

A thermally conductive composition comprises an ionic liquid and a filler material comprising thermally conductive particles. The composition is used to provide a low thermal impedance interface between two members, such as a heat generating electronic component and a heat sink or other heat receiving member. Also disclosed is a method of transferring heat between two members wherein a thermally conductive interface is interposed intermediate heat transfer surfaces of the members, the interface comprising the thermally conductive composition and an optional conformal sheet.

### CROSS-REFERENCE TO RELATED APPLICATION

This application claims benefit under 35 USC 119(e) of U.S. Provisional Application Ser. No. 62/755,808, filed Nov. 5, 2018, which application is incorporated herein for all purposes by reference thereto.

### FIELD OF THE INVENTION

The present disclosure relates to a thermally conductive material that is useful in the construction of a variety of electrical and electronic devices, and more particularly to a thermally conductive composition comprising an ionic liquid matrix optionally containing particulate fillers that is useful in facilitating the transfer of heat generated in a device during its operation to an adjacent heat sink.

### TECHNICAL BACKGROUND

Electrical, electronic, and optoelectronic components, such as semiconductors, transistors, integrated circuits (ICs), discrete devices, light emitting devices (LEDs), and others known in the art, are intended to operate within a normal operating temperature range. However, such components inexorably generate heat during normal operation. If the heat is not adequately removed, the temperature of the component may rise, possibly to a temperature above the intended normal operating temperature range. A sufficiently high temperature will cause immediate damage, but prolonged exposure even to a lower temperature may eventually affect performance of the component adversely and compromise operation of device(s) associated therewith. In extreme cases, the component can be damaged irreversibly over time. In general, the miniaturization and increasing clock rates of modern digital electronics have exacerbated the challenge of thermal management, both by increasing the rate of heat production and by reducing package size, which, in turn, impedes heat transfer by reducing the area from which heat can be extracted.

To avoid these problems, electronic devices are frequently constructed by thermally coupling heat-producing components to a heat sink, from which the heat can be transferred more readily to the external environment by a variety of means, including radiation, or by natural or forced convection via air or liquid. Ordinarily, the heat sink is constructed of a metal with high heat conductivity; often it includes fins or other extended structures to provide extra area for heat transfer to the outside world. Aluminum is most commonly used, because it is light and relatively inexpensive, has good thermal conductivity, and can easily be formed in desired shapes, e.g. by casting, stamping, or extrusion. Although more expensive and denser, copper is sometimes used because of its excellent thermal conductivity. In some situations, particularly ones involving high power and large components and devices, the heat sink includes coolant passages through which a coolant liquid like water or a gas can be circulated. A heat pipe may also be used. The efficiency of heat transfer from the heat generating device to the heat sink is quantifiable by an interfacial thermal impedance: the lower the thermal impedance, the greater the flow of heat.

The best heat transfer occurs through areas in which the mating surfaces of the electronic component and the heat sink are in actual contact. However, surfaces of real materials are never completely smooth, even if they appear so to the unaided eye. Instead, they have some degree of natural roughness at a microscopic level. Thus, two objects that would be regarded as in “contact” in the ordinary, macroscopic sense of the term are in actual contact only at certain high points on the respective surfaces, with multiple intervening microscopic air spaces, which are poor thermal conductors. Therefore, the effective contact area is ordinarily much lower than the apparent macroscopic contact area, so the effective thermal impedance of the interface increases.

In addition, surfaces may be bowed, and not perfectly flat. Whereas surface roughness is associated with spatial frequencies often regarded as occurring on a length scale on the order of 1 μm to 1 mm, surface waviness is associated with longer-length departures from flatness, e.g., having spatial frequencies greater than 1 mm. If one or both of the contacting surfaces are wavy, then large gaps will exist between the surfaces when they are urged together. These large gaps reduce further the area of effective thermal contact and increases the impedance.

Nevertheless, in the context of the present disclosure, it is to be understood that two solid surfaces are regarded as being in contact if they have been urged together by a force that is sufficient to cause microscopic contact, but without causing perceptible deformation or damage to either contacting surface. Similarly, a surface of a solid element and a conformable rubber or other polymeric material are regarded herein as being in contact if the urging force does not cause damage to or deform the solid surface.

Thermal contact between a device and a heat sink or other substrate is commonly improved by interposing a thermal interface material (TIM) between the opposing surfaces. The material is intended to fill as much as possible of the space between the surfaces, including both microscopic air spaces due to surface roughness and other larger-scale gaps, e.g. due to surface waviness. Displacing air and replacing it with a solid or liquid would, in principle, improve the heat transfer coefficient by a factor of the order of 1000 in the local area affected. To be effective, a TIM must be highly conformal, so that either a grease or a pliant, polymeric sheet, and frequently both, are normally used. Both greases and polymeric sheets used as TIMs may incorporate thermally conductive filler materials in particulate form, such as alumina, silica, boron nitride, zinc oxide, or the like, to further enhance their intrinsic conductivity.

However, existing TIMs of both types are known to have undesirable features. Polymeric sheets generally cannot flex enough to fully accommodate the actual roughness and non-planarity of even polished surfaces. As a result, a grease or other fluid-like substance with a suitable viscosity is almost invariably included, since the force urging the respective workpieces together will cause the grease to displace air in the surface irregularities and thus better conform to the actual surface topology, while maintaining a relatively thin bond line between the mating surfaces.

Such a configuration is depicted by FIG. 1, which shows schematically an exemplary electronic assembly 10 of the prior art. Heat producing electronic component 12 and heat receiving member 14 have respective first and second heat transfer surfaces 13, 15 that have irregular surface topologies at a microscopic level. The irregularities may include undulations, asperities, microcracks, or other such defects. It is understood that for clarity of illustration, the size and shape of the gap and the undulations in FIG. 1 are exaggerated and not to scale, and that FIG. 1 is not intended to depict waviness at a longer length scale that may also exist. A polymeric conformal sheet 16 is interposed between surfaces 13 and 15. The assembly is fabricated by dispensing a suitable amount of thermal grease 18 on each side of sheet 16, then urging component 12 and member 14 into opposing relationship by a vertically directed force that may be sufficient to cause some deformation of intervening sheet 16, but not enough to cause surface damage to, or deformation of, component 12 or member 14. The force causes thermal grease 18 to be extruded within the gaps, so that ideally it completely fills the valleys of the undulating surfaces, thus providing a thermal pathway for heat conduction over the entire area of both surfaces. However, in practice, some regions of air space invariably remain, so that the effective contact area is less than the apparent geometrical area of the respective surfaces. In other embodiments (not shown), conformal sheet 16 is omitted, so the surfaces are brought into direct contacting relationship, with a single layer of thermal grease directly bridging between as much of the opposing surfaces as possible. It is preferred, but not required, that second heat transfer surface 15 of heat receiving member 14 be at least as large as first heat transfer surface 13, to maximize the heat transfer. To minimize the effective thermal impedance of the interface, the thermal grease layer is ideally made as thin as possible.

Silicone thermal greases based on polydimethylsiloxane (PDMS) are most common, though hydrocarbon-based greases are also used. The ability of PDMS-based greases to conform to rough surfaces is enhanced by the relatively low glass transition temperature (Tg) of PDMS materials, which makes their molecular chain structure very flexible at room temperature and above, and by a low surface energy, which enables the grease to wet out the opposing surfaces well. The chemical stability signaled by a relatively high thermal decomposition temperature provides an advantage over non-silicone polymers. Changing the PDMS chain length permits control of rheology, facilitating effective deposition processes.

However, the low surface energy of ordinary silicone greases also deleteriously permits them to spread through and contaminate a fabrication environment. For example, the grease may find its way to other parts under manufacture, the equipment used in the manufacturing processes, and the physical infrastructure of the manufacturing environment. This can compromise other processes within the manufacturing environment, leading to defects in the finished products. The area over which the silicone greases spread is very large, making cleaning expensive, and at best a temporary solution. Most silicone greases also exhibit an undesirable phenomenon called pump-out, wherein repeated thermal cycling during the customary end use of a device causes the filled grease to crack, extrude from the joint area, or phase separate.

Phase change materials (PCM) such as wax, stearic acid, and polyethylene glycol have also been used as TIMs. At temperatures above ambient, they typically have low viscosity and flow well to wet the mating thermal surfaces, and so provide good heat transport. In their cooled state, they are relatively rigid and do not flow. However, thermal cycling and the solid-liquid transition these materials undergo may result in undesirable mechanical stress being imposed on devices thermally contacted to heat sinks.

Non-silicone solutions that use other hydrocarbon-based organic polymers and oils are also available. While they mitigate some of the problems with silicones, they suffer from other drawbacks, including higher Tg's, lower decomposition temperatures, and less robust crosslinking chemistries. Because of these concerns, researchers are continually looking for better alternatives for the matrix of thermal greases.

### SUMMARY

An aspect of the present disclosure provides a thermally conductive composition capable of functioning as a thermal grease. The composition comprises:
(a) an ionic liquid; and
(b) a filler material comprising thermally conductive particles, fibers, or a combination thereof.

In some embodiments, the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions.

The filler material of the present disclosure may comprise thermally conductive particles selected from the group consisting of particles of metals or metal alloys, oxides, borides, nitrides, carbides, silicates, sulfides, selenides, diamond, graphite, graphene, carbon nanotubes, and mixtures thereof. Thermally conductive fibers of boron nitride, aluminum oxide, or carbon may also be included.

Another aspect provides an electronic assembly comprising:
(a) a heat generating electronic component having a first heat transfer surface;
(b) a heat receiving member having a second heat transfer surface; and
(c) a thermally conductive composition comprising an ionic liquid;
and wherein the first and second heat transfer surfaces are in contacting relationship with the thermally conductive composition being interposed therebetween to provide a heat conduction path from the heat generating electronic component to the heat receiving member.

In some embodiments, the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions.

Optionally, the thermally conductive composition further comprises a filler material comprising thermally conductive particles, fibers, or a combination thereof.

Yet another aspect provides a method of extracting heat comprising:
(a) providing a heat generating electronic component having a first heat transfer surface;
(b) providing a heat receiving structure having a second heat transfer surface, the first and second heat transfer surfaces being situated in contact, with a thermally conductive composition interposed between the heat transfer surfaces, whereby an enhanced heat conduction path is provided from the heat generating electronic component to the heat receiving structure; and
(c) cooling the heat receiving structure, whereby heat is extracted from the heat generating electronic component,
and wherein the thermally conductive composition comprises an ionic liquid.

In some embodiments, the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions. Optionally, the thermally conductive composition further comprises a filler material comprising thermally conductive particles, fibers, or a combination thereof.

A still further aspect provides a thermal management assembly, comprising:
(a) a first member having a first heat transfer surface;
(b) a second member having a second heat transfer surface, the members being disposed with their respective heat transfer surfaces in opposing relationship; and
(c) a thermally conductive interface interposed intermediate the first and second heat transfer surfaces to provide a thermally conductive pathway therebetween, the thermally conductive interface comprising a thermally conductive composition comprising an ionic liquid.

In some embodiments, the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions. Optionally, the thermally conductive composition further comprises a filler material comprising thermally conductive particles, fibers, or a combination thereof.

Yet another aspect provides a method of transferring heat from a first member to a second member, comprising:
(a) situating a first member having a first heat transfer surface and a second member having a second heat transfer surface with their respective transfer surfaces in opposing relationship;
(b) interposing a thermally conductive interface intermediate the first and second heat transfer surfaces to provide a thermally conductive pathway therebetween, the thermally conductive interface comprising a thermally conductive composition comprising an ionic liquid.

In some embodiments, the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions. Optionally, the thermally conductive composition further comprises a filler material comprising thermally conductive particles, fibers, or a combination thereof.

### BRIEF DESCRIPTION OF THE DRAWINGS

The invention will be more fully understood and further advantages will become apparent when reference is made to the following detailed description of the preferred embodiments of the invention and the accompanying drawings, wherein like reference numerals denote similar elements throughout the several views and in which:

FIG. 1 depicts in schematic, cross-sectional view a thermal interface of the prior art; and

FIG. 2 depicts in schematic, cross-sectional view an electronic assembly in accordance with the present disclosure, comprising an integrated circuit mounted on a circuit board and a heat sink in thermal communication with the integrated circuit through a thermally conductive composition interposed between the integrated circuit package and the heat sink.

### DETAILED DESCRIPTION

Certain terminology may be employed herein for clarity and convenience of description, rather than for any limiting purpose. For example, terms of direction, such as “forward,” “rearward,” “right,” “left,” “upper,” “lower,” “vertical,” and “horizontal” pertain to depictions in drawings to which reference is made or orientations of workpieces in their intended use, as indicated by context. Terminology of similar import other than the words specifically mentioned above likewise is to be considered as being used for purposes of convenience rather than in any limiting sense.

Various aspects of the present disclosure relate to a thermally conductive composition in which part or all of the matrix material is an ionic liquid. The composition is appointed for use as a thermal interface material (TIM). The composition optionally contains filler material comprising thermally conductive particles or fibers of one or more types. Depending on the desired end use, the particles or fibers may be either electrically insulating or electrically conductive. Other aspects include the use of such a composition to provide an improved thermal pathway between an electrical or electronic device and a heat sink, a substrate, or other like structure, and a method of enhancing the transfer of heat between members in an electronic or thermal management assembly.

As used herein, the term “ionic liquid” refers to a liquid composed of ions that is fluid at a temperature at or below 100° C. An embodiment of the present thermally conductive composition comprises an ionic liquid whose ions are those of an organic salt, including, without limitation, salts wherein the cation is one of pyridinium, pyridazinium, pyrimidinium, pyrazinium, imidazolium, pyrazolium, thiazolium, oxazolium, triazolium, or a derivative thereof and the anion is one of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, or any other fluorinated anion.

The thermally conductive composition optionally includes a filler material comprising thermally conductive particles or fibers or a combination thereof to enhance the effective thermal conductivity of the composition.

Useful filler materials include, without limitation, thermally conductive particles of one or more of metals or metal alloys, oxides, borides, nitrides, carbides, silicates, sulfides, selenides, diamond, carbon, graphite, graphene, and carbon nanotubes or the like. In another embodiment, the thermally conductive particles may comprise one or more of boron nitride, aluminum oxide, silicon carbide, aluminum nitride, zinc oxide, single wall carbon nanotubes, multiwall carbon nanotubes, and diamonds. Also contemplated are thermally conductive fibers, such as fibers of boron nitride, aluminum oxide, and carbon.

For example, and without limitation, useful metallic particles include silver, copper, aluminum, nickel, tin, antimony, gallium, indium, and alloys thereof, and particles of metal that are coated with another metal or organic or inorganic compound.

Oxides of aluminum, silicon, zinc, magnesium, beryllium, chromium, titanium, zirconium, antimony, and silver, are exemplary. Suitable nitrides include boron nitride in hexagonal, cubic, or another form, silicon nitride, and aluminum nitride. Suitable carbides include silicon carbide, boron carbide, and titanium carbide. Suitable borides may include titanium boride and tungsten boride. Silicates may include sodium silicates, aluminum silicates, aluminum sodium silicates, magnesium silicates, aluminum magnesium silicates, and other natural and synthetic clays.

The thermally conductive particles and fibers in the present composition are optionally coated with an organic or inorganic coating to improve any of their dispersibility, rheology, or functional properties. Certain of the particles may also have a native oxide coating.

In some embodiments, the size of the filler particles is not subject to any particular limitation. As used herein, “particle size” is intended to refer to “average particle size” or d₅₀, by which is meant the 50% (or median) volume distribution size. The particle size distribution may also be characterized by other parameters, such as d₉₀, meaning that 90% by volume of the particles are smaller than d₉₀, and d₁₀, meaning that 10% by volume of the particles are smaller than d₁₀. Volume distribution size may be determined by a number of methods understood by one of skill in the art, including but not limited to laser diffraction and dispersion methods employed by a Microtrac particle size analyzer (Montgomeryville, Pa.). Laser light scattering, e.g., using a model LA-910 particle size analyzer available commercially from Horiba Instruments Inc. (Irvine, Calif.), may also be used.

In various embodiments, the filler particles have a d₅₀ value that ranges from a lower limit that is one of 0.2, 0.5, 0.75, 1, or 2 μm to an upper limit that is one of 5, 10, 20, 50, 75, or 100 μm, as measured using the LA-910 particle size analyzer.

In some embodiments, a single type of thermally conductive particle is used, while multiple types of particles are combined in other embodiments. For example, the particles may differ in at least one of chemical composition, average particle size, or particle shape. In an embodiment, the filler material comprises particles of at least two types that differ in average particle size d₅₀.

To minimize the thermal impedance for heat transfer between two structures, the area of contact should be maximized and the spacing between the structures minimized. However, geometrical and structural considerations ordinarily limit the maximum area available for the heat transfer surfaces in actual devices. The separation or gap between the two contacting surfaces should also be minimized to the extent possible, subject to the limits resulting from surface roughness and other irregularities.

Typically, the intrinsic thermal conductivity of the filler particles in a grease is higher than that of the matrix material. Thus, the efficacy of heat transfer between objects is best improved by using a thermal grease formulated so that as much as possible of the gap space between the objects is bridged by the filler particles. In addition, pathways in which the heat flow paths traverse as few particle-matrix interfaces as possible provide better conductivity. An ideal thermal grease thus has as high as possible a volumetric loading of particles with a suitable particle size distribution. The composition ideally excludes particles large enough to increase the separation or gap between the two connected surfaces, while not including an excessive number of very small particles that would unduly increase the number of particle-matrix interfaces. However, increasing the particle loading generally increases the composition's viscosity. Thus, the loading typically is limited to ensure the composition can be dispensed satisfactorily with the desired process equipment. In some cases, the included particles are somewhat abrasive, so too a high a loading may damage nozzles or other conduits through which the composition must pass during deposition.

In some embodiments, a plurality of filler material types may be used that differ in one or more of chemical composition, particle shape or morphology, particle size distribution, particle coating, or the like. For example, having particles of different sizes favors dense packing, with smaller particles occupying interstices between adjacent large particles. Useful particles may also have a variety of morphologies, including, without limitation, spherical, ellipsoidal, acicular, rod-like, plate-like, and irregular shapes.

Any of the foregoing particles or fibers may be coated or otherwise surface treated. For example, and without limitation, surface treatment may be done to improve the particles' dispersibility in the matrix material, to avoid undesirable agglomeration, or to improve the rheology and other end-use properties of the present composition.

In an embodiment, the thermally conductive particles comprise 8-95% by weight of the thermally conductive composition, depending on both the particles' shapes and the relative densities of the filler and the matrix. In an embodiment, thermally conductive, monodisperse, spherical particles comprise up to about 65% by volume of the thermally conductive composition. For polydisperse fillers, or mixtures of fillers with different shape morphologies, the composition may contain up to about 90% by volume of filler.

The proportions of the matrix material and the filler material in the present composition can vary in accordance with the method of applying the composition and the end use properties desired. In various embodiments, the present composition contains thermally conductive particles in an amount ranging from a lower limit that is one of 8, 10, 20, 30, 40, or 50% to an upper limit that is one of 60, 70, 75, 80, 85, 90, or 95%, by weight of the total composition.

The matrix material in some embodiments of the present thermally conductive composition further comprises one or more silicone materials. The term “silicone,” as used herein, refers to any member of the class of compounds known as polyorganosiloxanes. These materials are polymers that comprise a backbone consisting essentially of alternating silicon and oxygen atoms. Each silicon atom, by valence, will have two additional substituents. These substituents may comprise, without limitation, methyl groups, alkyl groups, phenyl groups, aryl groups, vinyl groups, ethenyl groups, hydroxyl or hydride functionality. Other substituents that are commonly known in the art are also contemplated. In various embodiments, the weight average molecular weight of the silicone used in the present composition can vary from Mw=100 to Mw=200,000 daltons. Mixtures of silicone materials with different molecular weights are commonly used and contemplated herein. Any of the silicones can be terminated with methyl groups, alkyl groups, amino groups, anhydride groups, phenyl groups, aryl groups, vinyl groups, ethenyl groups, hydroxyl or hydride functionality.

Representative polyorganosiloxanes useful in the present formulation also include, without limitation, examples provided in U.S. Pat. Nos. 5,011,870, 7,329,706, and 8,633,276. Each of said patents is incorporated herein in its entirety for all purposes by reference thereto.

The present composition is formulated to have a consistency and rheology that render it suitable for deposition and the intended end use. In particular, the composition preferably has a stability compatible not only with the requisite manufacturing, shipping, and storage, but also with conditions encountered during deposition. Ideally, the rheological properties of the vehicle are such that it lends good application properties to the composition, e.g., including stable and uniform dispersion of solids, appropriate viscosity and thixotropy for deposition, and appropriate wettability of the solids and the substrate on which deposition will occur.

Thus, other constituents commonly used in thermally conductive compositions may also be included in any effective amount. Non-limiting examples include rheology control agents or other flow modifiers; antioxidants; solvents; wetting agents, dispersants, or surfactants; antioxidants or antimicrobials; antifoaming agents; pigments; opacifying agents; tackifiers; lubricants; stabilizers; flame retardants (such as decabromodiphenyl oxide); film-reinforcing polymers or other like agents; and spacer or filler particles (such as fumed silica).

The present thermally conductive composition exhibits high thermal conductivity and is useful in fabricating heat transfer structures having a low interfacial thermal impedance. Ordinarily, compositions that include metallic filler materials have higher thermal conductivity than ones that use non-metallic or other fillers that are only poorly electrically conductive or electrically insulating. However, many applications demand an electrically non-conductive material. In various implementations, the present thermally conductive composition is electrically non-conductive but exhibits a thermal conductivity that is at least 0.5, 1.0, 1.5, 2, 2.5, or 3 W/m·K. For example, the thermal conductivity may range from a lower limit that is one of 0.2, 0.5, 1.5, or 1.75 W/m·K to an upper limit that is one of 2, 2.5, or 3 W/m·K. An interface fabricated with an electrically non-conductive but thermally conductive material of the present disclosure interposed between respective heat transfer surfaces may have a thermal impedance between 0.01 and 10 K-cm²/W. In an embodiment, the interfacial thermal impedance is less than about 5, 2, 1.5, 1, 0.75, or 0.5 K-cm²/W.

Values of thermal conductivity and interfacial thermal impedance are conveniently determined using methods such as that provided in ASTM Standard Test Method D5470-17. (ASTM Standard Test Methods are promulgated by ASTM International, West Conshohocken, Pa. ASTM Standard D5470-17 is incorporated herein in its entirety for all purposes by reference thereto.)

The inclusion of ionic liquid beneficially permits formulation of thermally conductive compositions with a wide range of viscosities and good thermal conductivity, but without a concomitant increase in vapor pressure. In some instances, silicone-based compositions are limited by the need to provide both rheological properties consistent with feasible deposition processes and long-term device stability and a sufficiently high loading of conductive particulate material to attain a required level of thermal conductivity.

The present thermally conductive composition is typically produced by combining the ingredients with a mechanical system. The constituents may be combined in any order, as long as they are uniformly dispersed and the final formulation has characteristics such that it can be successfully applied during end use. Mixing methods that provide high shear may be especially useful.

### II. Fabrication of Electronic and Thermal Management Assemblies

Another aspect of the present disclosure provides an electronic or thermal management assembly in which the foregoing thermally conductive composition is used to facilitate heat transfer from one member to another.

In one representative embodiment, an electronic assembly comprises a heat generating electronic component in contacting relationship with a heat receiving member. The thermally conductive composition is interposed between them to provide an improved heat conduction path.

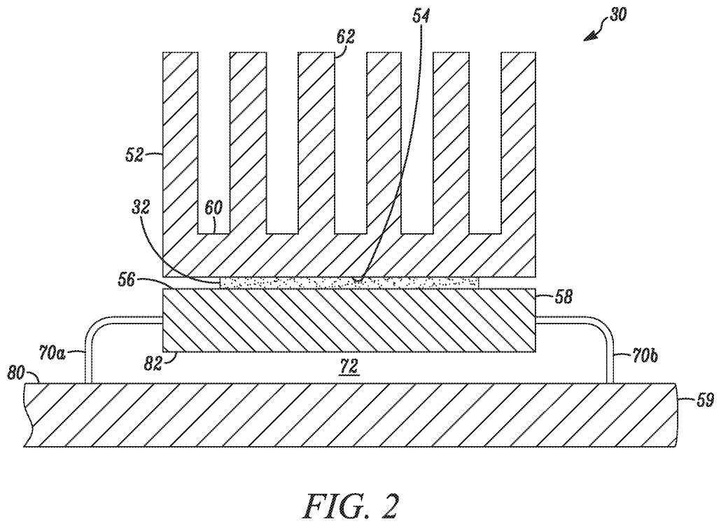

An exemplary implementation of such an electronic assembly is depicted generally at 30 in FIG. 2. A heat-generating electronic or optoelectronic component 58 is secured to an associated printed circuit board (PCB) 59 or other substrate. Component 58 is commonly a microchip, an integrated circuit, microprocessor, transistor, or other optoelectronic or power semiconductor device, but may also be any other electrically powered device or other subassembly such as a diode, diac, triac, relay, resistor, capacitor, inductor, transformer, or amplifier that generates heat during operation. However, any other heat generating source is also contemplated. Typically, component 58 will have a normal operating temperature range of about 60-125° C.

Heat sink 52 and component 58 are disposed with their respective heat transfer surfaces 54 and 56 in contacting relationship, with thermally conductive composition (depicted schematically at 32) disposed between the surfaces to function as a thermally conductive interface that enhances thermal contact. For the sake of clarity of illustration, the thickness of composition 32 is exaggerated.

For illustrative purposes, heat sink 52 is depicted as having a plate-fin configuration, in which a plurality of cooling fins 62 extend perpendicularly from a generally planar base section 60 on a side opposite heat transfer surface 54. In other embodiments the fins may extend at other angles, or the projections could have other shapes, such as a series of posts or pins. Such projections all increase the surface area of the heat sink, providing enhanced heat transfer to the ambient. In most instances, natural circulation of ambient air provides sufficient removal of heat from heat sink 52, but in other embodiments, a circulating fan (not shown) is used to provide a forced air flow to increase heat transfer.

Heat sink 52 typically is formed of a metallic material having high thermal conductivity, such as aluminum, copper, or an alloy, and a heat capacity relative to that of component 58 that make it effective in dissipating heat received from component 58. Alternatively, heat sink 52 could be formed of a ceramic material such as alumina.

In the embodiment depicted, surfaces 54 and 56 are substantially the same in size, and encompass substantially all of the respective surfaces of heat sink 52 and component 58.

However, it is to be understood that other configurations are also contemplated, including ones in which the actual contact area is smaller than that of either or both of the respective heat transfer surfaces 54, 56 and ones in which an extra amount of composition 32 is present, such that the spacing between the components is somewhat increased. Ordinarily, it is beneficial for the respective heat transfer surfaces to be as large as possible, and for the members to be in close contact, to facilitate the transfer of heat from the heat generating component to the heat receiving structure.

In other configurations (not shown), heat sink 52 is replaced by another heat receiving structure that provides either active or passive heat transfer to the ambient, such as a heat exchanger, cold block or plate, heat pipe, or heat spreader structure. In an implementation, a cold block has with passages through which water or other coolant fluid may passed. Another implementation provides an actively cooled plate, e.g. one that operates electrically based on the Peltier effect. In still other embodiments, a printed circuit board, housing, chassis, or any other structure having sufficient heat capacity to provide for heat removal may be used for this function. In all these embodiments, the interposition of the present thermally conductive composition facilitates the extraction of heat from the heat generating component so that its operating temperature can be held within desirable limits.

With continuing reference to FIG. 2, component 58 is electrically connected to conductive traces (not shown) present on circuit board 59 by soldering using one or more pair of pins, one representative pair of which is referenced at 70a-b. Alternatively, the connection might be made with solder balls or leads of any other convenient type. Pins 70 additionally may support component 58 above board 59 to define a gap, represented at 72, which might be about 3 mils (75 microns), between surface 80 of circuit board 59 and bottom surface 82 of component 58. Alternatively, component 58 may be received directly on board 59.

In other embodiments (not shown), the thermally conductive interface further comprises an intermediate member, such as a conformal pad, that is situated intermediate the heat transfer surfaces. The faces of the pad are in contacting relationship with the respective heat transfer surfaces. The present thermally conductive composition is situated between the pad and at least one, and preferably both, of the heat transfer surfaces.

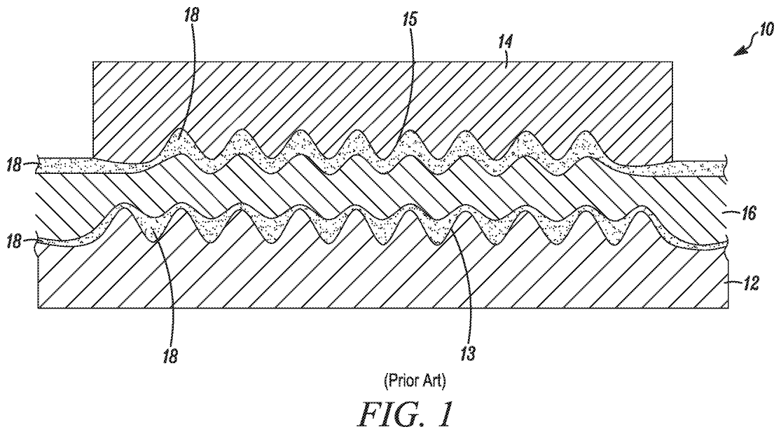

During construction, the thermally conductive composition 32 may be applied to either or both of the thermal surfaces of the structures by any suitable technique including, without limitation, brushing, spraying, ink jet printing, nozzle printing, stenciling, screen printing, or syringe deposition. The material may be spread across the requisite area of either or both surfaces in the initial deposition or by mechanical means thereafter. Often, the respective parts are urged into contact by applying a modest mechanical force that is sufficient to extrude the thermally conductive composition fully into the interface region, without causing perceptible deformation or damage to either contacting surface. Like the surfaces shown in FIG. 1, heat transfer surfaces 54 and 56 are never perfectly planar, and instead have microscopic irregularities of the same general sort. In addition, surfaces may be bowed, and not perfectly flat. The thermal grease fills the gaps created by nonplanar surfaces. Thus, it is desirable that as many of the air spaces as possible, and ideally all, are filled with composition 32, so that heat transfer capability from component 58 is maximized. Typically, the amount of composition 32 used is sufficient to provide full coverage of the first and second surfaces and fill the surface roughness, but without increasing the separation between the respective members.

Another aspect of the present disclosure pertains to a thermal management assembly in which the present thermally conductive composition is used to facilitate heat transfer between plural members of the assembly.

In an implementation, the thermal management assembly comprises a first member and a second member, which have respective first and second heat transfer surfaces. The members are situated with their first and second areas in opposition and in contacting relationship, with a thermally conductive interface therebetween. The interface comprises the present thermally conductive compound and provides a thermal pathway through which heat can flow from the first member to the second member.

In an implementation, the thermally conductive interface further comprises an intermediate member, such as the conformal pad discussed above.

The present thermally conductive composition is most commonly used in configurations in which a heat generating component of any type is to be cooled by conducting the generated heat by to a heat sink or other member, from which it can be dissipated externally. However, the composition also is beneficially used in configurations in which a member is to be intentionally heated by conducting heat thereto from an external heater, with the composition acting to ensure good conduction from the heat source itself or an intermediate structure.

In still other aspects, the composition is used to ensure that a member is thermally bonded to another member by a highly thermally conductive path, so that both members are at substantially the same temperature. For example, a sensor such as a thermistor or thermocouple is often attached to, or otherwise associated with, another member, and good thermal contact is needed to ensure that the temperature indicated by the sensor accurately reflects the temperature of that member. Other applications in which the present thermally conductive composition is used to improve thermal communication between two members of any type are also contemplated.

The heat transfer surfaces of the members in the foregoing assemblies are most often nominally planar, but the present composition may also be used in other configurations (not shown). For example, the heat transfer surfaces might be cylindrical, with one surface having the shape of part or all of an outside cylindrical surface, and the other being part or all of an inside cylindrical surface matched in diameter to allow the surfaces to mate. In another example, one or both of the heat transfer surfaces might be bowed or wavy.

### III. Method of Extracting Heat

A related aspect of the present disclosure provides a method of extracting heat from an electronic component. Specifically, operation of the electronic component in configurations such as those described above and depicted in FIG. 2 results in heat generation. That heat is transferred to a heat receiving structure through a thermal pathway in which the presence of a thermally conductive composition reduces the thermal impedance of the interface formed by contacting areas of the respective heat generating and heat receiving components. The heat receiving structure is cooled, whereby heat is extracted from the heat generating electronic component. That heat extraction can occur by any suitable means, including one or both of convective and radiative transfer from the heat receiving structure to the ambient atmosphere. Alternatively, the heat receiving structure can comprise a cold block having passages through which water or other cooling fluid is passed, or an actively cooled plate, e.g. one that operates electrically based on the Peltier effect.

### EXAMPLES

The operation and effects of certain embodiments of the present invention may be more fully appreciated from a series of examples, as described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Examples 1-17

### Preparation and Testing of Thermally Conductive Compositions

Thermally conductive compositions were prepared and tested in accordance with the present disclosure. The ionic liquids used in the examples are set forth in Table I, which provides chemical names, abbreviations used, and the structure of each substance.

TABLE I
Names, abbreviations, and structures of ionic liquids

| | Abbre- | |
|---|---|---|
| Name | viation | Structure |
| 1-ethyl-3- methyl- imidazolium ethyl sulfate | [EMIM] [E5O4] | 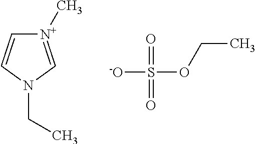 |
| 1-ethyl-3- methyl- imidazolium chloride | [EMI] [Cl] | 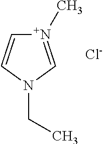 |
| 1-butyl-3- methyl- imidazolium tetrafluoro- borate | [BMIM] [BF4] | 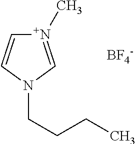 |
| 1-butyl-3- methyl- imidazolium hexafluoro- phosphate | [BMIM] [PF6] | 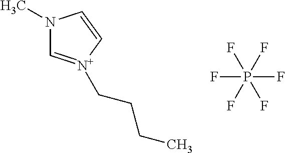 |

The filler materials used are set forth in Table II.

TABLE II
Names of fillers, descriptors, and sources

| Name | Descriptor | Size | ShapeMorphology | Source |
|---|---|---|---|---|
| alumina | 4-32 | 10 μm | spherical | Sanyo |
| | | (d₅₀) | | |
| alumina | AX1-10 | 1 μm (d₅₀) | spherical | Sanyo |
| boron nitride | NX-1 | 0.7 μm | spherical | Momentive |
| | | (d₅₀) | agglomerate | Performance |
| | | | | Materials |
| boron nitride | PT-120 | 20/90 μm | platelet | Momentive |
| | | (d₁₀/d₉₀) | | Performance |
| | | | | Materials |
| boron nitride | PT-110 | 6/20 μm | platelet | Momentive |
| | | (d₁₀/d₉₀) | | Performance |
| | | | | Materials |
| single-walled | SWCNT | (not | nanotube | Carbon |
| carbon | | measured) | | Nano- |
| nanotubes | | | | technologies |
| | | | | (CNI) |
| zinc oxide | ZnO | 0.7 μm | spherical | NOAH |
| | | (d₅₀) | | Technologies |
| silicon | SiC | <100 nm | spherical | Sigma-Aldrich |
| carbide | | (d₅₀) | | |
| aluminum | AIN | 12 μm | spherical | Strem |
| nitride | | (d₅₀) | | Chemicals |

### Compositions and Test Results

The various thermally conductive compositions listed in Table III below were prepared by combining the requisite amounts of ionic liquid and one or more particulate fillers using a planetary, centrifugal mixer (Model ARE-310, THINKY U.S.A. Inc., Laguna Hills, Calif.). The ingredients were placed in the mixer cup, along with zirconia beads to enhance mixing action. The formulation was agitated by the THINKY mixer, first for one minute at 2000 rpm, and then for an additional 30 seconds at 2200 rpm. The volume loading of filler material in each composition was calculated from the reported densities of its filler(s) and ionic liquid.

The thermal conductivity of each formulation was obtained using a commercial thermal conductivity tester (Model 1400 Thermal Interface Material Tester, Analysis Tech, Wakefield, Mass.), operated in accordance with the ASTM D5470-17 standard.

A sufficient amount of the formulation was applied to the lower platen of the tester. Then the upper platen was brought down into contact with the formulation until the material had spread out evenly between the two platens. After the measurement was obtained, the top platen was lowered by about 0.3 cm, and the measurement was repeated. This closing of the platens in such a stepwise fashion was repeated at least five times, thus providing the thermal resistivity (RA, units of K·cm²/W) at five unique thickness values. The measured thermal resistivity was plotted on the y-axis, and the thickness was plotted on the x-axis. The reciprocal of the slope of the best fit line was taken as the thermal conductivity (units of W/cm·K). The y-intercept of the best fit line was taken as the thermal interfacial resistivity. The measured value of the thermal conductivity for each composition was converted to its equivalent in the more conventional units of W/m·K, as reported in Table III.

TABLE III
Formulations, total solid loading, and resulting thermal conductivity of ionic liquid based compositions

| | | | | | | | Volume | Mass | |
|---|---|---|---|---|---|---|---|---|---|
| | | Filler | | Filler | | IL | loading | loading | Thermal |
| | Filler | #1 amount | Filler | #2 amount | | amount | of filler | of filler | Conductivity |
| Ex. | #1 type | (g) | #2 type | (g) | IL type | (g) | (%) | (%) | (W/m · K) |
| 1 | 4-32 | 26.0 | — | — | [EMIM][ESO4] | 5.0 | 62.3 | 83.9 | 2.54 |
| 2 | 4-32 | 29.0 | — | — | [EMIC] | 6.0 | 57.9 | 82.9 | 2.45 |
| 3 | NX-1 | 5.0 | — | — | [EMIM][ESO4] | 5.0 | 35.2 | 50.0 | 1.04 |
| 4 | NX-1 | 5.0 | — | — | [EMIC] | 5.0 | 32.8 | 50.0 | 1.14 |
| 5 | PT-120 | 5.5 | — | — | [EMIM][ESO4] | 5.0 | 37.4 | 52.4 | 1.42 |
| 6 | PT-120 | 4.5 | — | — | [EMIC] | 5.0 | 30.5 | 47.4 | 1.17 |
| 7 | PT-110 | 8.0 | — | — | [EMIM][ESO4] | 5.0 | 46.5 | 61.5 | 2.13 |
| 8 | PT-110 | 7.5 | — | — | [EMIC] | 5.5 | 39.9 | 57.7 | 1.31 |
| 9 | 4-32 | 15.7 | AX1-10 | 2.63 | [EMIM][ESO4] | 2.5 | 70.0 | 88.0 | 2.91 |
| 10 | 4-32 | 17.5 | AX1-10 | 2.93 | [EMIC] | 3.0 | 66.0 | 87.2 | 1.76 |
| 11 | 4-32 | 10.0 | — | — | [BMIMBF4] | 2.0 | 60.6 | 83.3 | 0.93 |
| 12 | 4-32 | 10.0 | — | — | [BMIMPF6] | 2.0 | 63.9 | 83.3 | 0.92 |
| 13 | CNT | 0.2 | — | — | [EMIM][ESO4] | 2.0 | 8.1 | 9.1 | 0.43 |
| 14 | SiC | 8.5 | — | — | [EMIM][ESO4] | 2.0 | 62.1 | 81.0 | 1.72 |
| 15 | ZnO | 6.75 | — | — | [EMIM][ESO4] | 2.0 | 42.7 | 77.1 | 0.54 |
| 16 | AlN | 6.0 | — | — | [EMIM][ESO4] | 3.0 | 43.2 | 66.7 | 1.22 |
| 17 | AlN | 5.3 | — | — | [BMIMBF4] | 2.5 | 43.8 | 67.9 | 0.82 |

The thermal conductivity of ionic liquids such as those used to prepare the formulations in Table III is expected to be approximately 0.15 W/m·K. Similar values are reported in the literature for the PDMS compositions frequently employed as matrix material in commercial thermal greases. The data set forth in Table III thus demonstrate improvement in thermal conductivity by a factor of about 3 to 21 resulting from the inclusion of conductive particles. The highest thermal conductivity exemplified is comparable to the 2.9 W/m·K reported for DOWSIL™ TC-5026 Thermally Conductive Compound, a representative PDMS-based thermal grease (available commercially from Dow Chemical Company, Midland, Mich.).

Having thus described the invention in rather full detail, it will be understood that this detail need not be strictly adhered to but that further changes and modifications may suggest themselves to one skilled in the art, all falling within the scope of the invention as defined by the subjoined claims.

For example, a skilled person would recognize that the choice of raw materials could unintentionally include impurities that may be incorporated into the thermally conductive composition during processing. These incidental impurities may be present in the range of hundreds to thousands of parts per million. Impurities commonly occurring in industrial materials used herein are known to one of ordinary skill.

The presence of the impurities would not substantially alter the chemical, rheological, and thermal properties of the thermally conductive composition or its functionality as a heat path for conduction of heat from a heat generating to a heat receiving component.

The embodiments of the thermally conductive composition and its constituent materials, as described herein, are not limiting; it is contemplated that one of ordinary skill in the art of electronic materials could make minor substitutions of additional ingredients and not substantially change the desired properties of the thermally conductive composition and devices fabricated therewith.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

In this specification, unless explicitly stated otherwise or indicated to the contrary by the context of usage, amounts, sizes, ranges, formulations, parameters, and other quantities and characteristics recited herein, particularly when modified by the term “about,” may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value.

What is claimed is:

1. A thermally conductive composition comprising in admixture:
(a) an ionic liquid; and
(b) a filler material comprising thermally conductive particles, fibers, or a combination thereof.

2. The thermally conductive composition of claim 1, wherein the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions.

3. The thermally conductive composition of claim 1, wherein the filler material comprises thermally conductive particles selected from the group consisting of particles of metals or metal alloys, oxides, borides, nitrides, carbides, silicates, sulfides, selenides, diamond, carbon, graphite, graphene, carbon nanotubes, and mixtures thereof.

4. The thermally conductive composition of claim 1, wherein the filler material comprises thermally conductive particles having an average particle size d₅₀ ranging from 0.2 μm to 100 μm.

5. The thermally conductive composition of claim 1, wherein the filler material comprises thermally conductive fibers of boron nitride, aluminum oxide, or carbon.

6. The thermally conductive composition of claim 1, wherein the filler material is present in an aggregate amount ranging from 5 to 95 wt % of the thermally conductive composition.

7. The thermally conductive composition of claim 1, wherein the filler material comprises thermally conductive particles of at least two types that differ in at least one of chemical composition, average particle size d₅₀, or particle shape.

8. The thermally conductive composition of claim 7, wherein the filler material comprises thermally conductive particles of at least two types that differ in average particle size d₅₀.

9. The thermally conductive composition of claim 1, further comprising a polyorganosiloxane.

10. The thermally conductive composition of claim 1, having a thermal conductivity of at least 0.5 W/m-K.

11. An electronic assembly comprising:
(a) a heat generating electronic component having a first heat transfer surface;
(b) a heat receiving member having a second heat transfer surface; and
(c) a thermally conductive composition comprising as recited by claim 1;
and wherein the first and second heat transfer surfaces are in contacting relationship with the thermally conductive composition being interposed therebetween to provide a heat conduction path from the heat generating electronic component to the heat receiving member.

12. The electronic assembly of claim 11, wherein the heat generating electronic component comprises at least one of an integrated microchip, microprocessor, transistor, or other light emitting or power semiconductor device.

13. The electronic assembly of claim 11, wherein the heat generating electronic component comprises at least one of a diode, relay, resistor, transformer, amplifier, or capacitor.

14. The electronic assembly of claim 11, wherein the heat receiving member comprises a heat sink, heat exchanger, cold plate, heat spreader structure, printed circuit board, housing, or chassis.

15. A method of extracting heat comprising:
(a) providing a heat generating electronic component having a first heat transfer surface;
(b) providing a heat receiving structure having a second heat transfer surface, the first and second heat transfer surfaces being situated in contact, with a thermally conductive composition as recited by claim 1 being interposed between the heat transfer surfaces, whereby an enhanced heat conduction path is provided from the heat generating electronic component to the heat receiving structure; and
(c) cooling the heat receiving structure, whereby heat is extracted from the heat generating electronic component.

16. A thermal management assembly, comprising:
(a) a first member having a first heat transfer surface;
(b) a second member having a second heat transfer surface, the members being disposed with their respective heat transfer surfaces in opposing relationship; and
(c) a thermally conductive interface interposed intermediate the first and second heat transfer surfaces to provide a thermally conductive pathway therebetween, the thermally conductive interface comprising a thermally conductive composition comprising an ionic liquid.

17. The thermal management assembly of claim 16, wherein the ionic liquid comprises cations selected from the group consisting of pyridinium, pyridazinium, pyrimidinium, pyrazinium, imidazolium, pyrazolium, thiazolium, oxazolium, triazolium, and any derivative thereof, and anions selected from the group consisting of [CH₃CO₂]⁻, [HSO₄]⁻, [CH₃OSO₃]⁻, [C₂H₅OSO₃]⁻, [AlCl₄]⁻, [CO₃]²⁻, [HCO₃]⁻, [NO₂]⁻, [NO₃]⁻, [SO₄]²⁻, [PO₄]³⁻, [HPO₄]²⁻, [H₂PO₄]⁻, [HSO₃]⁻, [CuCl₂]⁻, Cl⁻, Br⁻, I⁻, [BF₄]⁻, [PF₆]⁻, and any other fluorinated anions.

18. The thermal management assembly of claim 16, wherein the first and second heat transfer surfaces are disposed in contacting relationship, with the thermally conductive composition disposed therebetween.

19. The thermal management assembly of claim 16, wherein the thermally conductive interface further comprises an intermediate member and each of the first and second heat transfer surfaces is in contacting relationship with the intermediate member, and the thermally conductive composition is disposed between the intermediate member and at least one of the first and second heat transfer surfaces.

20. The thermal management assembly of claim 16, wherein the thermally conductive interface has a thermal impedance of less than about 1 K-cm²/W.

21. The thermal management assembly of claim 16, wherein the thermally conductive interface has a thermal conductivity of at least about 0.5 W/m-K.
